(19) United States
(12) Patent Application Publication
(10) Pub. No.: US 2023/0024036 A1
(43) Pub. Date: Jan. 26, 2023

(54) SYSTEMS AND METHODS FOR OPTIMIZING RISK AND TIME IN SAFETY CERTIFICATION OF CYBER-PHYSICAL SYSTEMS

(71) Applicants: Sandeep Gupta, Phoenix, AZ (US); Ayan Banerjee, Gilbert, AZ (US); Imane Lamrani, Phoenix, AZ (US)

(72) Inventors: Sandeep Gupta, Phoenix, AZ (US); Ayan Banerjee, Gilbert, AZ (US); Imane Lamrani, Phoenix, AZ (US)

(73) Assignee: Arizona Board of Regents on Behalf of Arizona State University, Tempe, AZ (US)

(21) Appl. No.: 17/813,257

(22) Filed: Jul. 18, 2022

Related U.S. Application Data
(60) Provisional application No. 63/222,472, filed on Jul. 16, 2021.

(51) Int. Cl. G06F 30/27

(52) U.S. Cl. CPC G06F 30/27

(57) ABSTRACT

Safety certification of cyber-physical system (CPS) such as autonomous cars or medical control systems are complicated especially due to the lack of transparency between the manufacturer and certifying authority. The manufacturer has significant restrictions in sharing knowledge with the certification authority. Further, given time constraints, it may not be feasible for the certification authority to examine internal details of the CPS. A system models the safety certification of CPS as an agile iterative game, where a manufacturer agent acting on behalf of the manufacturer and a certifier agent acting on behalf of a third-party certification entity aims to find an optimal subset of operating data to share for accurate safety certification. The certification agent, armed with CPS model mining methods and safety assessment analysis tools, aims to accurately assess safety of the CPS with the information shared.

### CROSS-REFERENCE TO RELATED APPLICATIONS

This is a non-provisional application that claims benefit to U.S. Provisional Patent Application Ser. No. 63/222,472 filed 16 Jul. 2021, which is herein incorporated by reference in its entirety.

### FIELD

The present disclosure generally relates to safety certification of cyber-physical systems, and in particular, to a system and associated method for optimizing cost, risk and time associated with information disclosure during safety certification of cyber-physical systems.

### BACKGROUND

Recent cases of fatal failures of safety-critical cyber physical systems (CPS) have renewed the discussion on the certification problem. One important direction is the presence of artificial intelligence (AI) in subcomponents of the CPS. AI-enabled systems that use AI to perform tasks such as supervised classification can often suffer from the “no oracle” problem, where the output for an unseen test case is non-deterministic and depends on environmental factors. A CPS has safety critical and non-safety critical components. Typically, uncertainties or non-determinism in AI subcomponents are not desirable in a safety-critical component. The non-safety critical components can use AI subcomponents. However, a CPS system in practice includes a lot more independent components than a standalone CPS. This introduces several novel complex interaction scenarios between the environment and the CPS which cannot be predicted during the design time. Hence, during certification of a CPS, it is nearly impossible to predict the safety consequences of uncertainty in an AI-based sub-component.

A case in point can be described with three separate instances of problems caused by Maneuvering Characteristics Augmentation System (MCAS) subcomponent in Boeing 737 Max 8 aircraft. The MCAS system was self-certified to be safe under certain scenarios. According to recent reports, all three cases were caused by sensor failures. Two of the three cases resulted in fatal disasters but in one case, the presence of a third co-pilot (a rare presence) helped to override the MCAS system and recover from a potential nose-dive. In the two fatal failure cases, the MCAS system was engaged during take-off which gives very little time for the pilots to effectively react (<12 mins according to reports). This clearly shows that the MCAS was potentially used in practice under very different scenarios than it was tested for. As such the coverage problem for AI enabled safety critical CPS can potentially encounter combinatorial explosion due to the presence of significant number of interacting external subcomponents and environmental conditions of use cases.

Model design and development is commonly used for CPS as it provides a non-invasive and inexpensive alternative to experiment driven analysis and design. There are several drawbacks to the traditional workflow of Model Based Design (MBD) when applied to AI enabled CPS.

It is with these observations in mind, among others, that various aspects of the present disclosure were conceived and developed.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1A is a diagram illustrating a process for model-based design, implementation and certification of safety-critical cyber-physical systems;

FIGS. 1B and 1C are simplified block diagrams showing a system for safety certification of a CPS;

FIG. 2 is a simplified diagram showing a cyber-physical system (CPS);

FIG. 3 is a simplified illustration showing an example automated lane change CPS provided for illustration purposes;

FIGS. 4A and 4B are simplified illustrations showing a certification “game” implemented by the system of FIGS. 1B and 1C,

FIG. 5 is a graphical representation showing a reach set for a reconstructed model of the CPS of FIG. 3 as reconstructed by the system of FIGS. 1B and 1C as compared to a true model of the CPS of FIG. 3;

FIG. 6 is a simplified diagram showing a safety assessment process implemented by the system of FIGS. 1B and 1C;

FIGS. 7A-7G are a series of graphical representations showing reach set variations of the CPS of FIG. 3 with changing parameter values;

FIG. 8 is graphical representations showing reach set variation of the CPS of FIG. 3 with changing subsets of operating data;

FIGS. 9A-9C are a series of process flows showing a method for CPS evaluation as implemented by the system of FIGS. 1B and 1C, and

FIG. 10 is a simplified diagram showing an exemplary computing system for implementation of the system of FIGS. 1B and 1C.

Corresponding reference characters indicate corresponding elements among the view of the drawings. The headings used in the figures do not limit the scope of the claims.

### DETAILED DESCRIPTION

Various embodiments of a system and associated methods for optimizing disclosure for safety certification of a cyber-physical system (CPS) are disclosed herein. The system can be computer-implemented and serves to aid manufacturers in preparing for safety certification by determining an optimal subset of information for disclosure to a real-world certifier agent. The system can receive subsets of operating data about the CPS, including input/output traces, guard conditions and modes of the CPS, and can perform various analyses to determine an optimal subset of operating data descriptive of the cyber-physical system that, if disclosed during the certification process, would result in a high probability of affirmative safety certification while minimizing risks associated with disclosure such as time, cost, and human risk.

The system models this optimization process as a cooperative game between (1) a first computer-implemented agent acting on behalf of a manufacturer whose goal is to receive an affirmative declaration of “safe” from a certifier agent while minimizing risks associated with disclosure and (2) a second computer-implemented agent acting on behalf of the certifier agent whose goal is to maximize certainty of a result of the safety evaluation. The system aims to reach an optimal subset of operating data that results in the highest probability of a “safe” evaluation result while ensuring minimization of risks associated with disclosure and while ensuring maximum certainty of the evaluation result. To accomplish this, the system can apply one or more model reconstruction techniques to a subset of operating data descriptive of the CPS to attempt to accurately reconstruct a model of the CPS, ensuring usefulness of the subset of operating data provided to a hypothetical certifier by the manufacturer. If the system is unable to reconstruct an accurate model, then the system can indicate to the manufacturer that more information or different information is needed to accurately complete certification. Conversely, if the system is able to reconstruct an accurate model, then the system can evaluate a safety of the CPS and provide an evaluation result, which can deem the CPS “safe” or “unsafe”. This process can be iteratively repeated until an optimal subset of operating data descriptive of the CPS is reached that maximizes probability of a “safe” certification result, maximizes certainty in the certification result, and minimizes risks associated with disclosure of the optimal subset of operating data.

The system can be implemented on a manufacturer side to aid manufacturers in finding an optimal subset of operating data descriptive of the CPS to disclose to a safety certifier. Further, in another aspect, the system can be implemented on a certifier side by attempting to reconstruct a model of the CPS based on information received from the manufacturer and applying safety analysis techniques to aid certifiers in evaluating the CPS.

### 1. Introduction

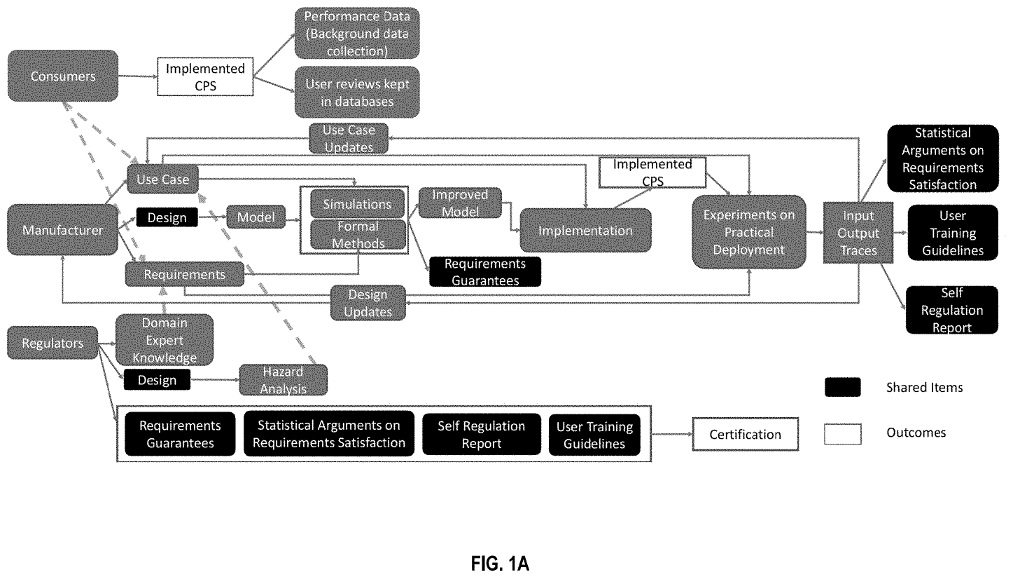

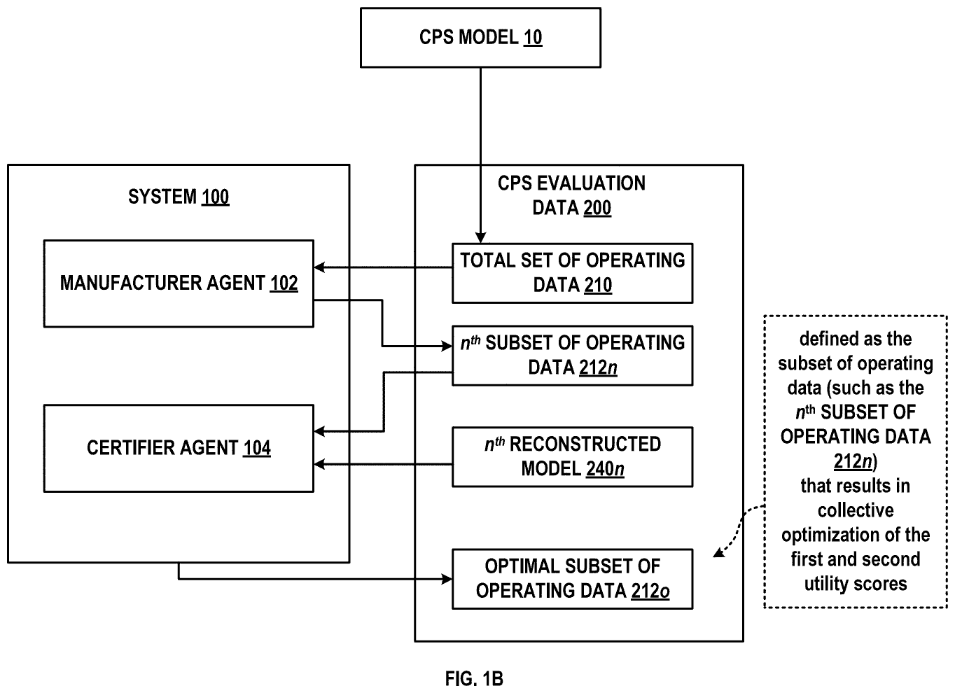

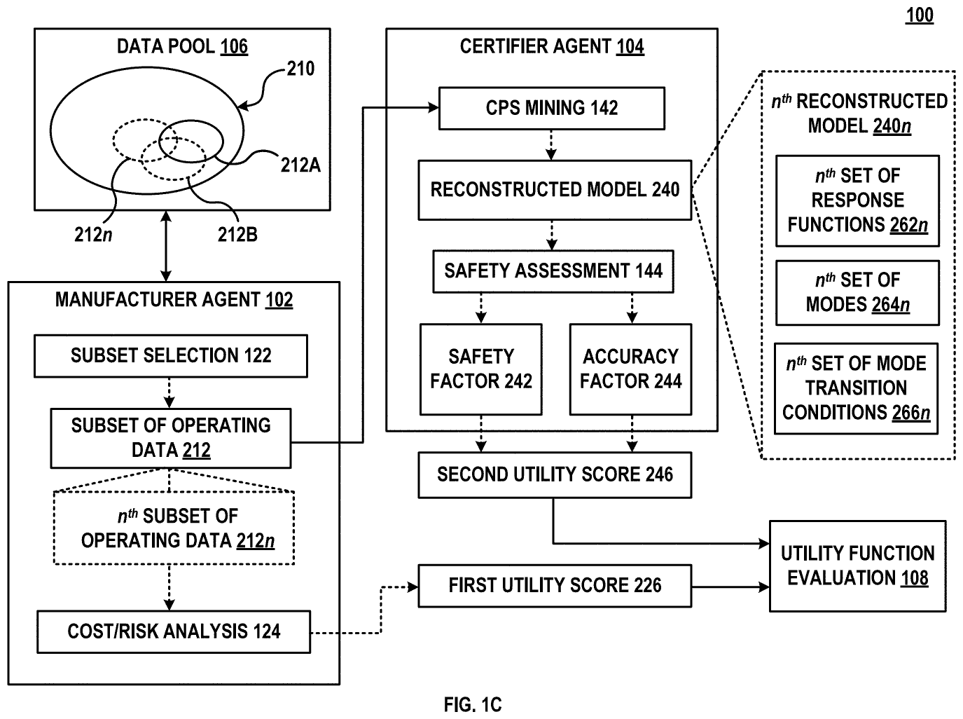

With reference to FIG. 1A, model-based approaches for safety certification of a CPS involves three participants: (1) a manufacturer, (2) a certifier, and (2) consumers. A first step of safety certification of a CPS involves generating a use case, a set of safety requirements and a design of the CPS. The set of safety requirements are typically generated through close collaboration with manufacturers and certifiers; oftentimes the consumer is included either through surveys or through consultation with domain experts. However, for a complex CPS, a multitude of safety requirements may be extracted through a hazard analysis step which may have to be prioritized for agile development and certification. Typical priorities include immediate safety hazards that can have fatal consequences. As a result, some of the more long-term safety risks may be ignored. For example, in case of the Minimed 670G artificial pancreas approved by the Food and Drug Administration (FDA) for automated insulin delivery in Type 1 Diabetic subjects, the primary safety requirement was avoidance of hypoglycemia. But recent post market evaluations along with collaborative effort by the research team shows that post-prandial hyperglycemia is a significant problem for the approved device, which has long term risks of high HbA1C levels and potential organ failure. Post prandial hyperglycemia is not discussed in approval documentation of the Minimed 670G. The drawback of the certification process is that test cases used for validating safety requirements are not updated based on usage data in the field.

A significant side effect of this drawback is that the 670G controllers are designed to be conservative in automated insulin delivery to avoid hypoglycemia, while the more aggressive bolus infusions are left for manual interventions from the user. Problems arise when errors in such interventions can introduce significant risks of hypoglycemia or hyperglycemia which the controller may not be tested to handle.

Self-Certification cannot be Independently Validated. The next steps in the certification workflow include, creating mathematical, simulation, or emulation models of the device and utilizing simulations and/or computational theory for validation of safety requirements. The output of this step yields a validated model and a set of requirements guarantees. The model design and use case is then used to implement the reconstructed model of the CPS. The reconstructed CPS is then subjected to experimental verification that generates traces of input-output data, which are then used for certification purposes. Although the certifiers include experts in the field, inner details of the CPS may not be disclosed due to proprietary issues, and only black box access to the components may not suffice for certification. Hence, several safety critical components of a CPS are self-certified, which requires the manufacturers to conduct tests on the components and generate a safety report. Such an approach is viable only if the regulators have the capability to independently verify the safety claims. This capability is currently not available.

Post market analysis and usage reviews are not incorporated in testing in a time manner. Once a CPS is certified, it is deployed in practice and is used by consumers. During usage in the field, the CPS may choose to log input-output traces so that it can improve on the efficacy or address safety concerns occurring in practice. In addition, in some cases, consumers can also report efficacy and safety issues with the CPS through reporting interfaces either hosted by the manufacturer or by the certifying agency. Recent times have seen fatal failures of safety critical CPS such as the Boeing 737 Max 8 crash and significant post-prandial hyper-glycemia in Type 1 Diabetic (T1D) subjects using the Minimed 670G artificial pancreas. Another big drawback of this process is that post-market reviews from consumers or data collected in the field are not provided as feedback to the design process in a timely and objective manner. Usage reviews of the Minimed 670G system from the MDR database highlight issues such as significant disagreement between the predicted low glucose suspend subsystem and glucose meter readings which have still not been addressed. Ethiopian airlines have reported another incident of MCAS misadventure where disaster was avoided, however the data was not used timely to at least alert consumers before disaster struck.

FIGS. 1B and 1C illustrate a system 100 that aims to improve certification effectiveness by facilitating an agile iterative certification “game” between a manufacturer agent 102 acting on behalf of a manufacturer and a certifier agent 104 acting on behalf of a third-party certification entity. The system 100 interacts with CPS evaluation data 200 to arrive at an optimal subset of operating data 212o that enables a third-party evaluator entity to successfully assess a safety of a CPS model 10 while minimizing risks and costs associated with the optimal subset of operating data 212o. The manufacturer agent 102 initially starts the process at a subset selection block 122 by providing a subset of operating data 212 (e.g., an n^{th} subset of operating data 212n; if n=1, a first subset of operating data 212A) of a total set of operating data 210 of the CPS. The manufacturer agent 102 selects the subset of operating data 212 with the goal of affirmative safety certification with minimal sharing of knowledge to the certifier agent 104 about the internal operation of the CPS. As such, the manufacturer agent 102 can include a cost-risk analysis block 124 that evaluates a first utility score 226 of a first utility function associated with costs and risks of disclosure of the subset of operating data 212.

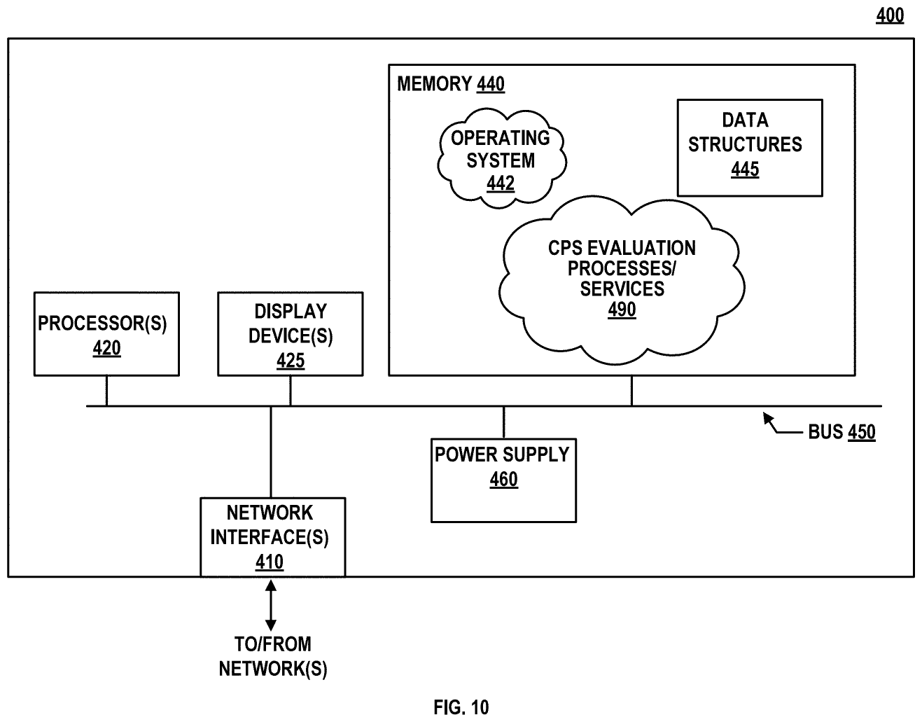

The certifier agent 104 then attempts to extract or otherwise infer the safety critical information about the CPS from the subset of operating data 212 in the form of a reconstructed model 240 (e.g., an n^{th} reconstructed model 240n; if n=1, a first reconstructed model 240A) and makes a recommendation on the safety status of the CPS based on the reconstructed model 240. The certifier agent 104 can include a CPS mining block 142 that applies one or more CPS mining techniques to infer the reconstructed model 240 based on the subset of operating data 212, which can include sets of parameters, sets of observed sampled variables (input/output traces), and sets of context-based operational conditions. The reconstructed model 240 can include sets of response functions, sets of modes and sets of mode transition conditions descriptive of the CPS. Note that the reconstructed model 240 is reconstructed based on the subset of operating data 212; if the subset of operating data 212 is insufficient, then the reconstructed model 240 will not be accurate. The certifier agent 104 can include a safety assessment block 144 that applies one or more safety assessment techniques to assess a safety of the reconstructed model 240, which can yield at least one of a safety factor 242 and an accuracy factor 244 that are used to determine a second utility score 246 of a second utility function associated with the safety and accuracy of the reconstructed model 240 as determined by the certifier agent 104. The first utility score 226 associated with the costs and risks of disclosure of the subset of operating data 212 and the second utility score 246 associated with the safety and accuracy of the reconstructed model 240 (inferred based on the subset of operating data 212) can be collectively evaluated at a utility function evaluation block 108 of the system 100 to determine if the subset of operating data 212 is satisfactory. The subset of operating data 212 must satisfy both the first utility function and the second utility function to maintain minimal costs and risks of disclosure of the subset of operating data 212 but must also preserve the ability of a third-party certification entity to reconstruct an accurate model of the CPS using the subset of operating data 212. The system 100 can display, at a display device 425 (FIG. 10), safety information and accuracy information associated with an accuracy of the n^{th} reconstructed model. In some embodiments, the safety information can include an “unsafe” declaration of the n^{th} reconstructed model 240n indicating that the n^{th} reconstructed model 240n results in the safety factor meeting or exceeding a safety threshold value; alternatively, depending on the formulation of the safety factor, the safety information includes an “unsafe” declaration of the n^{th} reconstructed model 240n indicating that the n^{th} reconstructed model 240n results in the safety factor being below a safety threshold value. Similarly, the accuracy information can include an “inaccurate” declaration of the n^{th} reconstructed model 240n indicating that the n^{th} reconstructed model 240n results in an accuracy factor being below an accuracy threshold value.

If the certifier agent 104 is unable to establish safety based on the reconstructed model 240 due to inaccuracy, the system 100 can require the manufacturer agent 102 to provide a new subset of operating data 212 (e.g., a second subset of operating data 2128) to improve the capability of an accurate safety assessment. The manufacturer agent 102 at this point can continue the game by challenging the certification result and releasing more knowledge or accept the certification result and end the game. If the reconstructed model 240 is accurate but reveals that the CPS is unsafe, then the system 100 can deem the CPS unsafe.

In some embodiments, if implemented on the manufacturer's side, the system 100 might have access to a data pool 106 that includes the total set of operating data 210 of the CPS and can repeat this process in an iterative fashion, selecting one or more subsets of operating data 212 and evaluating them to arrive at an optimal subset of operating data 212o (e.g., the first subset of operating data 212A, the second subset of operating data 212B, . . . , an n^{th} subset of operating data 212n, depending on whichever subset of operating data 212 yields the best results). Upon selecting the subset of operating data 212, the system 100 can evaluate a risk of disclosure of the subset of operating data 212, which can include considerations such as monetary cost to acquire the operating data, time cost to acquire the operating data, human risk involved in acquisition or disclosure of the operating data, and risk involved in disclosure of intellectual property such as trade secrets present within the operating data. Then, the system 100 can attempt to infer the reconstructed model 240 based on the subset of operating data 212 using one or more CPS model mining techniques and can assess an accuracy factor of the reconstructed model 240. Following assessment of the accuracy factor of the reconstructed model 240, the system 100 can then evaluate a safety of the reconstructed model 240 using one or more safety certification techniques and provide an evaluation result, which can deem the CPS “safe” or “unsafe”.

In some embodiments, if the system 100 has access to the total set of operating data 210 of the CPS, then the system 100 can iteratively select and evaluate new subsets of operating data 212 (e.g., the first subset of operating data 212A, the second subset of operating data 212B, . . . , the n^{th} subset of operating data 212n) until the system 100 reaches the optimal subset of operating data 212o that maximizes probability of a “safe” certification of the CPS (in which the reconstructed model 240 is accurate and the safety analysis of the reconstructed model 240 deems the CPS “safe”) while minimizing risks associated with disclosure of the optimal subset of operating data 212o such as monetary cost, time cost, and human risk.

In other embodiments, if the system 100 is implemented on the manufacturer's side but does not have access to the total set of operating data 210 of the CPS, then the system 100 can still receive a subset of operating data 212 from a user (e.g., the manufacturer), infer the reconstructed model 240 based on the subset of operating data 212, assess an accuracy factor of the reconstructed model 240, and assess safety of the CPS as represented by the reconstructed model 240. If the system 100 is unable to accurately infer the reconstructed model 240, then the system 100 can indicate to the user at the display device 425 that more information is required to accurately complete the assessment. The user can then provide a new subset of operating data 212 to the system 100 for assessment or end the process. This process can be iteratively repeated with the user selecting the new subset of operating data 212 at their discretion until the user ends the process. If the system 100 is able to accurately reconstruct the reconstructed model 240 but deems the CPS system “unsafe” during the safety assessment step, then the manufacturer may have to re-examine the CPS system to identify and resolve problems.

In some embodiments, if the system 100 is implemented on the certifier's side, the system 100 can receive a communicated subset of operating data 212 (e.g., the first subset of operating data 212A) descriptive of the CPS, infer the reconstructed model 240 based on the communicated subset of operating data 212, assess an accuracy factor of the reconstructed model 240, and assess safety of the CPS as represented by the reconstructed model 240. If the system 100 is unable to accurately infer the reconstructed model 240, then the system 100 can indicate to the user (e.g., the certifier) at the display device 425 that more information is required to accurately complete the assessment. The user can then request a new subset of operating data 212 (e.g., the second subset of operating data 212B) from the manufacturer for re-assessment or end the process. This process can be iteratively repeated with the manufacturer providing the new subset of operating data 212 at their discretion until the user ends the process. If the system 100 is able to accurately reconstruct the reconstructed model 240 but deems the CPS system “unsafe” during the safety assessment step, then the certifier can inform the manufacturer that they may have to re-examine the CPS system to identify and resolve problems.

Generally, for an n^{th} iteration of m total iterations, an n^{th} subset of operating data 212n of the total set of operating data 210 yields an n^{th} reconstructed model 240n including an n^{th} set of response functions 262n indicative of an n^{th} set of modes 264n and an n^{th} set of mode transition conditions 266n that dictate transitions between each mode of an n^{th} set of modes 264n. After the system 100 reaches a conclusion about the n^{th} subset of operating data 212n, the process can be repeated with an (n+1)^{th} iteration, where an (n+1)^{th} subset of operating data yields an (n+1)^{th} reconstructed model including an (n+1)^{th} set of response functions indicative of an (n+1)^{th} set of modes and an (n+1)^{th} set of mode transition conditions that dictate transitions between each mode of an (n+1)^{th} set of modes. Ultimately, the optimal subset of operating data 212o is the n^{th} (n+1)^{th}, . . . or (n+m)^{th} subset of operating data when the n^{th}, (n+1)^{th}, . . . or (n+m)^{th} subset of operating data results in collective optimization of the first utility score 226 and the second utility score 246.

To show an instance of the system 100 with data collected in the field, the system 100 is validated on a CPS that implements an automated lane change control system for a vehicle.

### 2. Cyber-Physical Systems Overview

A CPS model includes interactions between a controller model and a physical system model. This interaction is modeled by a set of ordinary differential equations (ODEs) representing dynamics of the physical system as controlled by the controller model. The CPS model includes a set of operational contexts (e.g., “control modes”) where predefined initial and transient conditions are satisfied. During real-world operations, a subset of the system's variables are observed, usually in the form of input-output traces, but can also include intermediate variable values. Hence, sampled data can be recorded for certification purposes.

### 3. Example: Automated Lane Change System

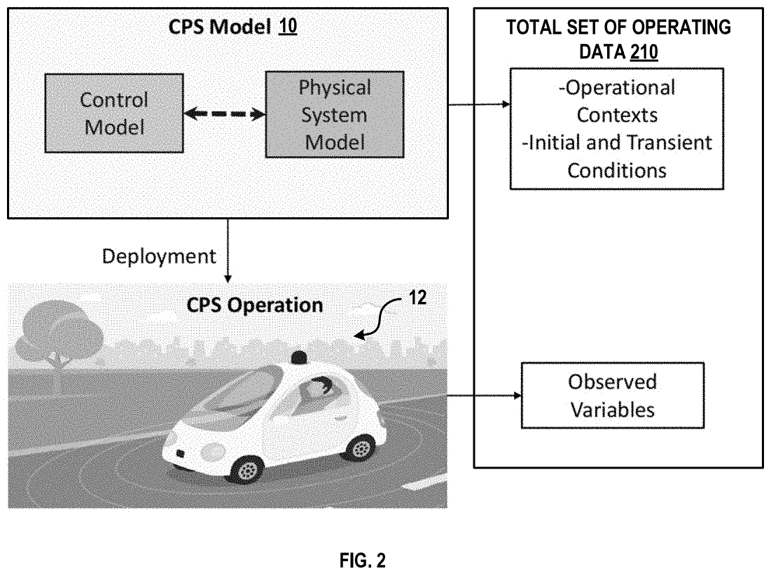

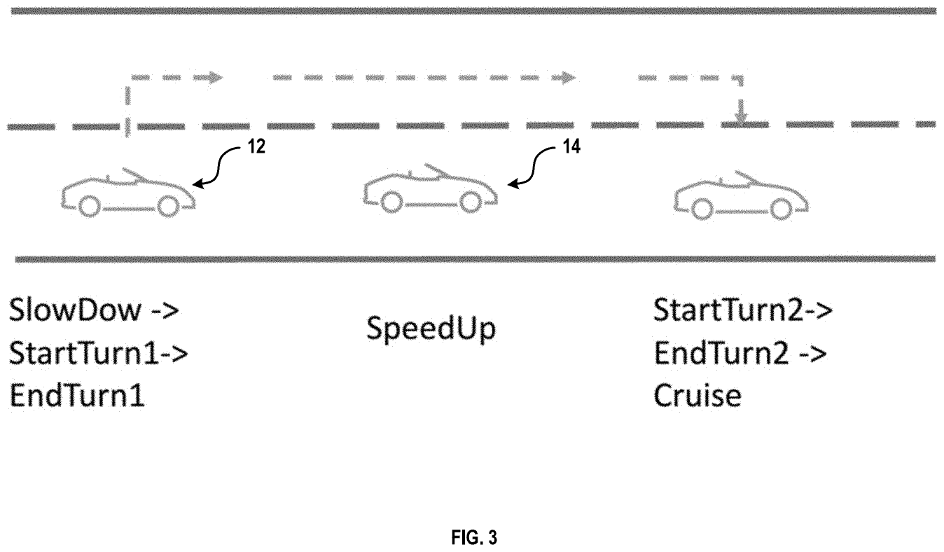

For the purposes of this disclosure, consider an automated lane change (ALC) system as a CPS model 10 (FIG. 2) to be certified having a set of operating data 22, although note that other examples of CPSs can be considered as well. As shown in FIG. 3, a goal of the automatic lane change system of a first autonomous vehicle 12 is to automatically overtake a second vehicle 14 directly in front of the first autonomous vehicle 12 and then return to its initial lane. The first autonomous vehicle 12 can be modeled by a set of ordinary differential equations of continuous variables representing the dynamics of the CPS model 10 in different control modes (Eq. 1). For purposes of illustration, the CPS model 10 can include the following control modes: (1) SlowDown where the first autonomous vehicle 12 slows down until a safe distance between the two vehicles is maintained, (2) StartTurn1 where a steering direction is adjusted to move to the next lane, (3) EndTurn1 where a steering angle is adjusted to stay in the passing lane and (4) SpeedUp mode to accelerate and pass the second vehicle 14. Finally, the steering angle is adjusted during modes (5) StartTurn2 and (6) EndTurn2 to return the initial lane and successfully complete the passing maneuver. A final mode can include (7) Cruise. The variables of the vehicle can include an absolute position s and velocity v of the first autonomous vehicle 12 with respect to the second vehicle 14 in the (x, y) coordinates where x represents the direction of the road and y the orthogonal direction. w represents the steering angle and a represents the acceleration. The parameter set {β1, . . . , β6} of the governing ODEs vary from one mode to the other to model how dynamics of the system change in every mode.

\dot{s}ₓ=bvₓ−c

\dot{v}ₓ=aaₓ

s_{y}=hv_{y}

\dot{v}_{y}=kv_{y}

\dot{w}=mw

\dot{a}ₓ=dsₓ+e+fvₓ+gaₓ (1)

### 4. Certification Game

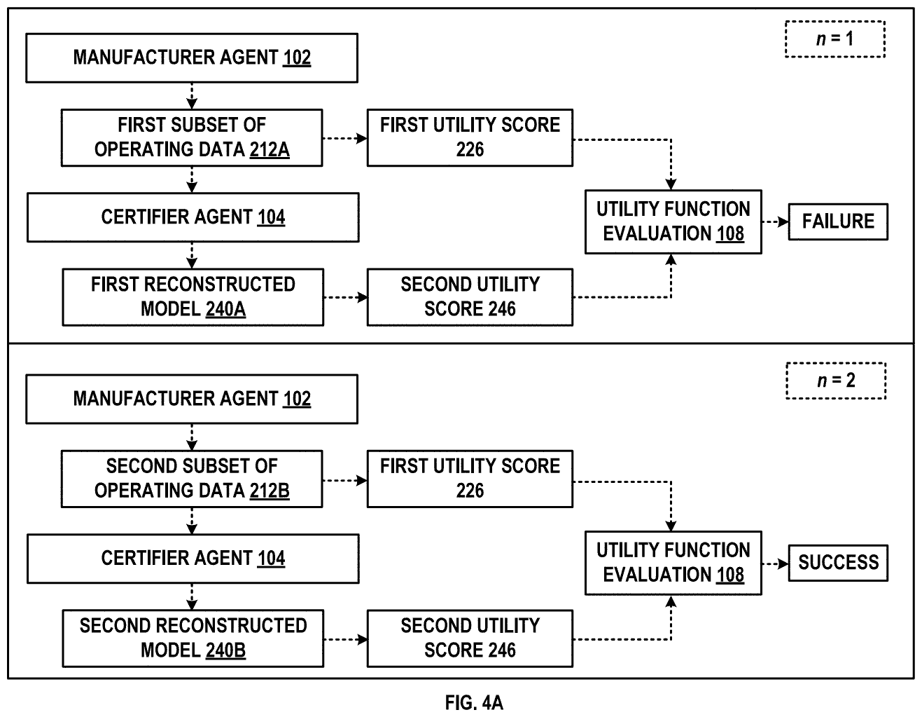

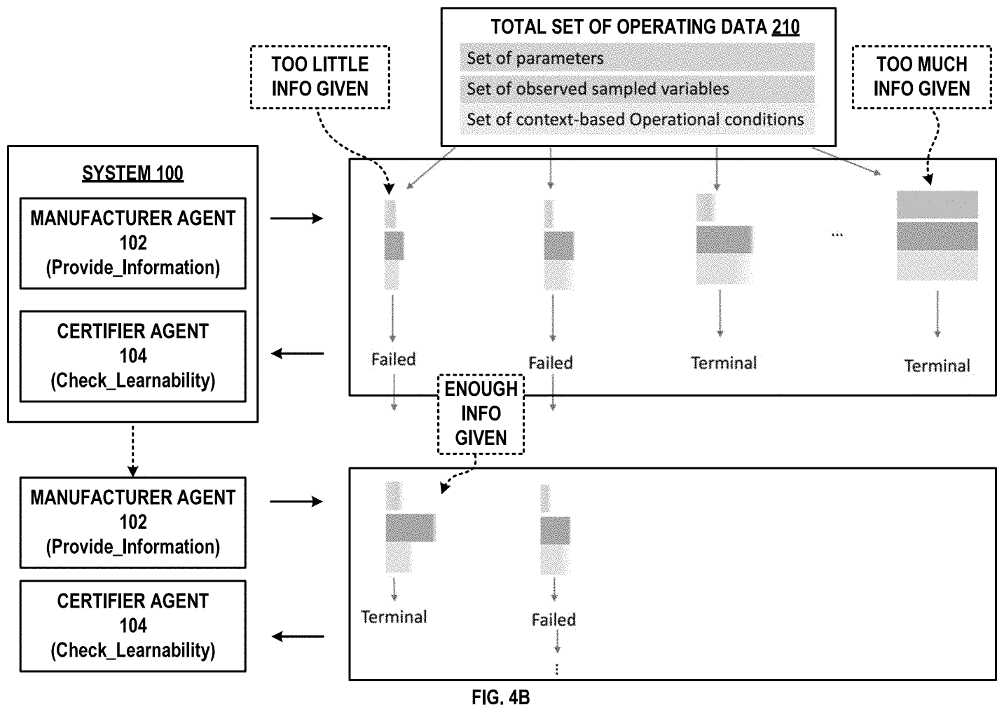

As shown in FIGS. 4A and 4B, the system 100 models the certification process as a game executed between two types of agents: the manufacturer agent 102, and the certifier agent 104. Both the manufacturer agent 102 and the certifier agent 104 share the same goal, that is the completion of the certification process, which is feasible if the certifier agent 104 is able to accurately reconstruct the reconstructed model 240 from the subset of operating data 212 that is shared to make a reliable safety conclusion. However, utility functions associated with the manufacturer agent 102, and the certifier agent 104 differ.

For the manufacturer agent 102, it is important to provide the certifier agent 104 with the subset of operating data 212 within a time and monetary cost budget while minimizing human risk and/or risks associated with disclosure of trade secrets and other intellectual property information. Hence, a first utility function associated with the manufacturer agent 102 aims to provide the least amount of operating data and a minimized visibility degree of the inner workings of the system. A first utility score 226 of the first utility function is indicative of the risks associated with retrieval and disclosure of the subset of operating data 212. Upon selection and/or receipt of the subset of operating data 212, the system 100 can evaluate the first utility score 226 with respect to the subset of operating data 212.

A second utility function associated with the certifier agent 104 aims to accurately learn the parameters of the CPS needed to complete the safety evaluation process and reach a favorable safety conclusion. A second utility score 246 of the second utility function is associated with an accuracy factor and a safety factor of the reconstructed model 240 elucidated by the subset of operating data 212. Upon inferring the reconstructed model 240 based on the subset of operating data 212 and assessing the safety of the reconstructed model 240, the system 100 can evaluate the second utility score 246 with respect to the subset of operating data 212.

The game facilitated by the system 100 involves the following actions alternatively taken by the manufacturer agent 102 and the certifier agent 104 until a terminal state is achieved. As such, the system 100 aims to reach the optimal subset of operating data 212o that that results in collective optimization of the first utility score 226 and the second utility score 246.

### 4.1 Step 1: Manufacturer Agent Action: Provide Information

In this step, the manufacturer agent 102 of the system 100 selects the first subset of operating data 212A from the total set of operating data 210 to share with the certifier agent 104. In some embodiments, the manufacturer agent 102 of the system 100 performs a cost, time, and risk analysis associated with providing the requested data, including costs and risks associated with experimentation and monitoring to obtain or disclose the requested data. The first utility function associated with manufacturer agent 102 aims to minimize the costs and risks associated with experimentation and monitoring to obtain or disclose the requested data while maximizing the probability of reaching an affirmative result of the safety assessment. The manufacturer agent 102 decides on the first subset of operating data 212A which can include observed variables, operational context-based data, context-based operational conditions, and various parameters to provide to the certifier using the following real-world considerations:

Observability: The possibility of monitoring a given variable during operation time is a function of: a) cost of sensors, b) availability of sensing at the required resolution, and c) intrusiveness of the sensor to the operation of the system.

Transparency: Even if variables and parameters are observable, regulatory requirements and constraints may prevent sharing of such data among stake holders.

Confidentiality: Internal parameters of the CPS often fall under trade secret rules and patent confidentiality agreements and may not be disclosed to a third-party certification entity.

Risk to human subjects: Oftentimes, experiments under certain data contexts can involve undue risks to human subjects. This not only increases cost but also time required to perform complicated procedures.

As such, the manufacturer may not be able to fulfill all requirements from the third-party certification entity. Hence, the manufacturer may choose to explore other possible paths.

For the example lane change CPS system described herein, assume that the first subset of operating data 212A includes aₓ and ω at a certain frequency

$$f = \frac{1}{τ} .$$

### 4.2 Step 2. Certifier Agent Action: Check Learnability

Based on the first subset of operating data 212A selected by the manufacturer agent 102, the certifier agent 104 of the system 100 attempts to recover the operational model of the cyber/physical process. The certifier agent 104 can use cyber-physical system mining methods such as HyMN to infer a first reconstructed model 240A from the first subset of operating data 212A. The second utility function associated with certifier agent 104 aims to maximize the accuracy of the first reconstructed model 240A. The reconstruction process can also use data contexts and corresponding operational conditions to extract reconstructed parameters of the first reconstructed model 240A. In some embodiments, at this point, the certifier agent 104 of the system 100 may “suggest” to the user one or more types of additional information that could be used to complete the certification process. At this step, the system 100 can display, at the display device 425, information related to the one or more types of suggested operating data. The certifier agent 104 identifies the following information required to accurately reconstruct the reconstructed model 240:

(1) Observable variables: These are the continuous variables of the process model.

For the example Lane Change (LC) CPS, the lane change controller has aₓ, vₓ, sₓ, v_{y}, s_{y}, and ω as continuous variables that can be observed.

(2) Data contexts: The observable variables should be observed under certain initial, transient and final value conditions.

In case of the LC CPS, to reconstruct the reconstructed model 240, full observability condition is enough since it is already a linear system. However, note that in this example, the first subset of operating data 212A does not include all observable parameters.

Based on the first subset of operating data 212A, the certifier agent 104 now attempts to reconstruct the operational model of the cyber/physical process of the CPS to yield the first reconstructed model 240A and evaluate an accuracy factor of the first reconstructed model 240A. The recovery process uses the data contexts and extracts one or more reconstructed parameters of the first reconstructed model 240A.

For the example of the LC CPS, the certifier agent 104 of the system 100 can apply the following steps to obtain the first reconstructed model 240A. Note that in practice, these steps will vary depending on the nature of the CPS that is being evaluated. These steps can be aided by various model reconstruction techniques.

1. Use the data collected for Mode 0. Compute the

$$\frac{{da}_{x}}{dt}$$

using Euler's method.

$$\frac{{da}_{x}}{dt} ( t ) = ( {a}_{x} ( t ) - {a}_{x} ( t - τ ) ) / τ \qquad ( Eq . 2 )$$

where

$$τ = \frac{1}{{f}_{\{ d , e , f \}}} .$$

Then, a linear regression between

$$\frac{{da}_{x}}{dt}$$

and aₓ(t) gives the parameter g.

2. Use the transient condition on the deceleration of the vehicle in Mode 0, to obtain a linear regression as follows:

at t=0,aₓ(0)=0. Which implies aₓ(1)=dsₓ(0)+e=fvₓ(0). (Eq. 3)

Here sₓ(0) and vₓ(0) are initial test conditions and hence are known as a part of test specification. In this example, aₓ is provided within the first subset of operating data 212A. Hence, the certifier agent 104 can utilize at least three different test cases to extract d, e and f.

3.: Another transient condition in Mode 0 is that vₓ(0)

Hence

$$\frac{{ds}_{x}}{dt} ( 0 ) = \frac{{ds}_{x}}{dt} ( 1 ) .$$

This implies the following linear regression:

$$at t = 0 and t = 1 , \qquad ( Eq . 4 )$$

$$\frac{{da}_{x}}{dt} ( 2 ) = d * ( {s}_{x} ( 0 ) + 2 * ( b * {v}_{x} ( 1 ) + c ) * τ ) + e + f * {v}_{x} ( 1 ) + g * {a}_{x} ( 1 )$$

Here, d, e, f, g are known, while b and c are the only unknowns. Hence with at least two test cases with different vₓ(0) and sₓ(0), the reconstructed parameters b and c can be obtained.

Action 4: Use initial transient conditions vₓ(2)=aaₓ(1)*τ+vₓ(0). Again, using multiple initial conditions a linear regression can be obtained that relates

$$\frac{{da}_{x}}{dt} ( t )$$

with aₓ(t) as follows:

$$\frac{{da}_{x}}{dt} ( 2 ) = d * ( {s}_{x} ( 0 ) + 2 * ( b * {v}_{x} ( 1 ) + c ) * τ ) + e + f * ( {v}_{x} ( 1 ) + {aa}_{x} ( 1 ) τ ) + {ga}_{x} ( 1 ) \qquad ( Eq . 5 )$$

here, the only unknown is a.

With the given approach, the certifier agent 104 could estimate values of reconstructed parameters of the first reconstructed model 240A using Equation 6.

a=0.1534,b=1,c=−3.02,d=−0.0099,e=0.737,f=−0.3,g=−0.506 (Eq. 6)

a=0.1,b=1,c=−2.5,d=−0.01,e=0.737,f=−0.3,g=−0.5 (Eq. 7)

Note that these are not the accurate parameters of the LC CPS, indicating that the first reconstructed model 240A is not accurate enough and that the first subset of operating data 212A is insufficient. As such, the first reconstructed model 240A would have an accuracy factor indicating that the first reconstructed model 240A elucidated by the first subset of operating data 212A is not accurate enough. The settings used in the Simulink replication of the LC CPS is shown in EQ. 7.

Sampling Requirements: For each observable parameter, a minimum sampling rate is required to ensure an error bound on the reconstructed constant parameters.

In case of the LC CPS, to accurately extract the value of d, e, f, within an error bound of E, the minimum sampling frequency required is given by:

$${f}_{\{ d , e , f \}} = \frac{d {s}_{x} ( 0 ) - e + f {v}_{x} ( 0 )}{ϵ - {a}_{x} ( 1 )} \qquad ( Eq . 8 )$$

where sₓ(0), vₓ(0), and aₓ(0) are the variable values when t=0 and t=1, respectively. These frequencies can be obtained from residual analysis of Eq. 1.

Duration Requirements: The duration requirements are dependent on the accuracy of the linear regression. In practice, the manufacturer is required to test the CPS until it satisfies the data requirements from the third-party certification entity.

### 4.3 Step 3: Certifier Agent Action: Terminal State and Safety Analysis

The certifier agent 104 of the system 100 can utilize several safety analysis techniques on the reconstructed model 240 to evaluate a safety factor of the CPS. One such example safety analysis technique includes a reachability analysis, that provides a set of states that the CPS can cover for a given set of initial conditions on the continuous variables, also called reach set. The reachability analysis can be applied to assess a safety of the reconstructed model 240 by checking intersection of the reach set with a safety threshold value on any variables of the CPS.

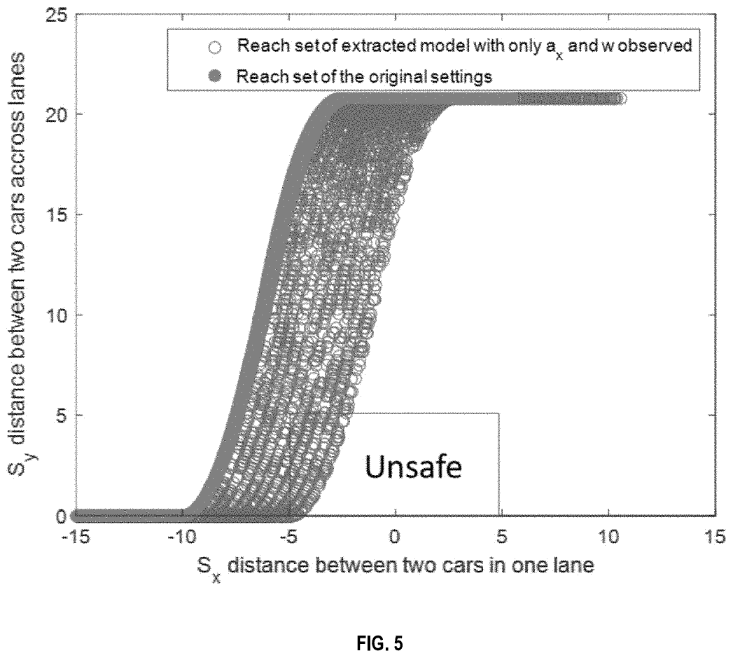

For the LC CPS in the example, a reach set can be obtained by using a reachability analysis tool such as the C2E2 reachability analysis tool. FIG. 5 shows a reach set for the first reconstructed model 240A in Eq. 6 and the CPS model 10 of Eq. 7.

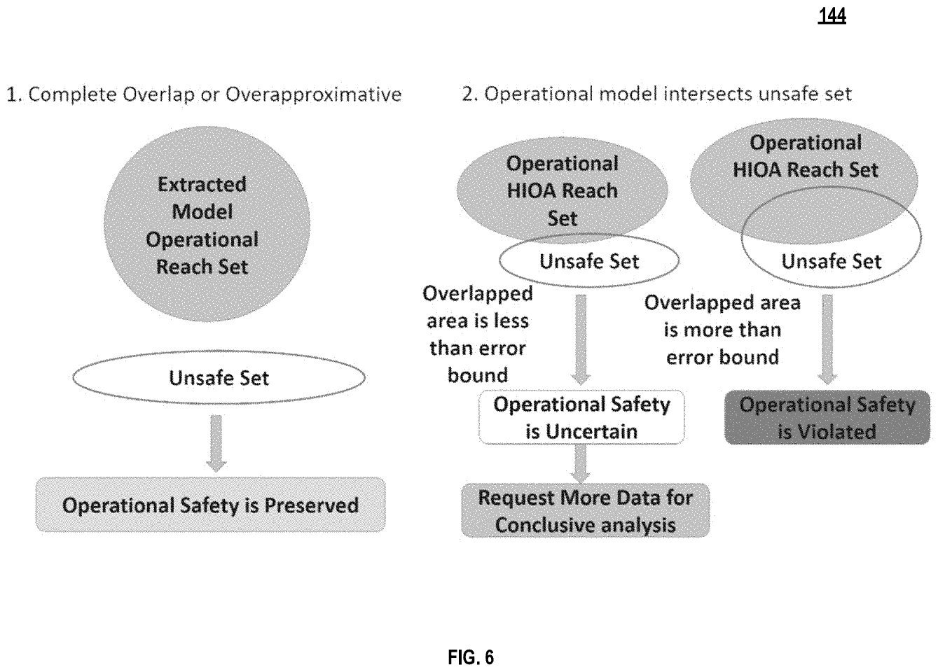

There can be three scenarios with the intersection of the reach set with the safety criteria as shown in FIG. 6.

The first scenario is when the reach set of the reconstructed model 240 does not intersect with the unsafe set. The certifier agent 104 can then certify the CPS to be operationally safe; in some embodiments, the process can end at this point (in other embodiments, the process can continue with the aim of finding the optimal subset of operating data 212o that minimizes disclosure costs and risks).

The second scenario is when the reach set of the reconstructed model 240 intersects with the unsafe set, but the intersection area is greater than error limits of the reach set computation due to inaccuracy of the reconstructed model 240. The certifier agent 104 can stop the iteration and deem the CPS unsafe.

In a third scenario, the intersection can be within the error limits of the analysis process. In such a case, the system 100 can provide the safety analysis results to the user, which can include the manufacturer and/or third-party certification entity. If the user is the third-party certification entity, then the third-party certification entity can ask the manufacturer to consider sharing the second subset of operating data 2128. If the user is the manufacturer, then the manufacturer can provide the second subset of operating data 2128 to share. At this point, the system 100 can repeat the “reconstruction” and “safety evaluation” steps using the second subset of operating data 212B.

In some embodiments, the system 100 can select the second subset of operating data 212B from the total set of operating data 210 without input from the manufacturer, and this process can continue in an iterative fashion until the optimal subset of operating data 212o is reached (e.g., the first utility function associated with disclosure cost and risk of the optimal subset of operating data 212o and the second utility function associated with reconstructability and safety of the optimal subset of operating data 212o are both optimized). In other embodiments, the user (e.g., the manufacturer) can manually select the second subset of operating data 212B for evaluation by the system 100.

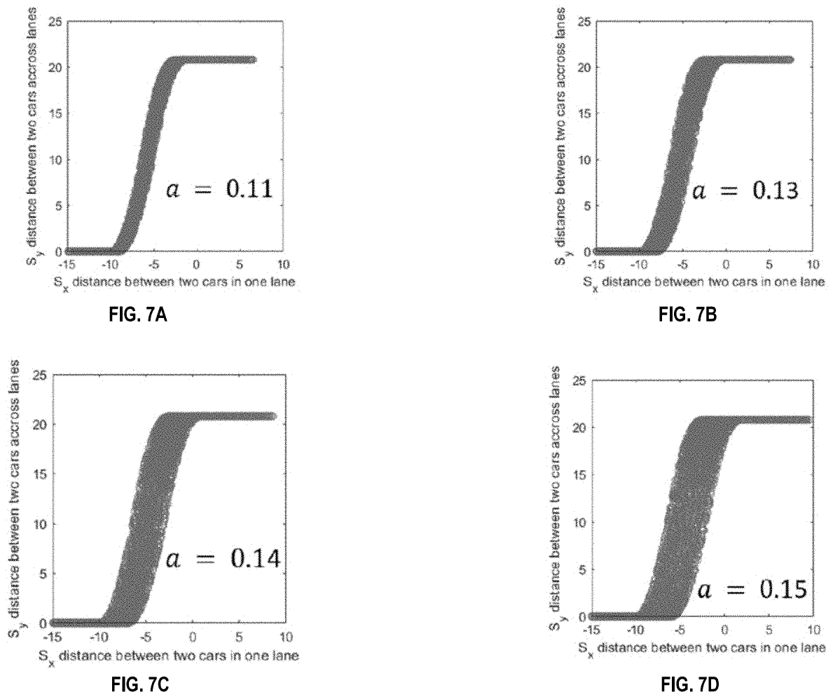

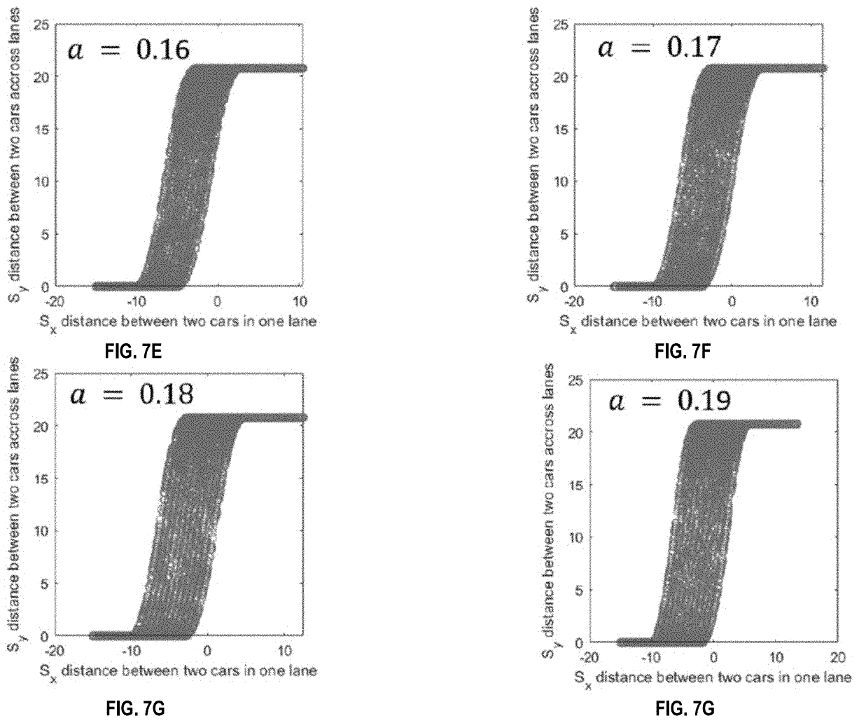

In the lane change example of the CPS model 10, if the manufacturer only gives the ax and w observations in the first subset of operating data 212A then the system 100 deems the CPS “unsafe”. An unsafe reach set is shown on the right-hand side in FIG. 6 signifying safe distance between two cars while changing lanes. The reason for the “unsafe” categorization can be due to error in parameter extraction, leading to inaccurate reconstruction of the first reconstructed model 240A. The certifier agent 104 of the system 100 can provide the user with information about how the reach set varies with each reconstructed parameter of the LC CPS. An example of such sensitivity analysis is shown in FIGS. 7A-7G that demonstrate how the reach set varies with changing parameter a of the CPS model 10.

### 4.4 Step 1 Repeated by Manufacturer: New Sensor

In the lane change example of the CPS model 10, the second subset of operating data 212B could include the velocity of the car or the location of the car. The velocity was already measured by the speedometer of the car. Hence, the manufacturer would not need to install any new sensors to obtain this information, and thus disclosure of the velocity of the car is associated with a lower cost of retrieval. However, to measure location, the manufacturer may need to install a proximity sensor, and thus disclosure of the location of the car is associated with a higher cost of retrieval. Thus, to save cost, the second subset of operating data 212B selected by the manufacturer agent 102 can include the velocity of the car.

4.5 Step 2 repeated by Certifier Agent: Model Reconstruction

Model Extraction: If vₓ, aₓ and ω are now available to the certifier agent 104 as the second subset of operating data 2128, then the certifier agent 104 can take the following steps to infer a second reconstructed model 240B using the second subset of operating data 212B:

1. Same as step 1 in Section 4.2 to obtain g.

2. Same as step 2 in Section 4.2 to obtain d, e and f.

3. Utilize linear regression between

$$\frac{{dv}_{x}}{dt}$$

computed using Euler's method and aₓ to obtain a.

4. The transient condition for

$$\frac{{da}_{x}}{dt}$$

can be utilized by considering two consecutive values and observing their difference.

$$\frac{{da}_{x}}{dt} ( 2 ) - \frac{{da}_{x}}{dt} ( 1 ) = d * ( {bv}_{x} ( 1 ) - c ) τ + f * ( {v}_{x} ( 2 ) - {v}_{x} ( 1 ) ) + g * ( {a}_{x} ( 2 ) - {a}_{x} ( 1 ) ) \qquad ( Eq . 9 )$$

here all variables except b and c are known.

Using the above-mentioned steps, the certifier agent 104 obtains a new set of reconstructed parameters of the second reconstructed model 240B as shown in Eq. 10.

a=0.102,b=1,c=−2.23,d=−0.0099,e=0.737,f=−0.3,g=−0.506 (Eq. 10)

4.6 Step 3 repeated by Certifier Agent: Safety Analysis

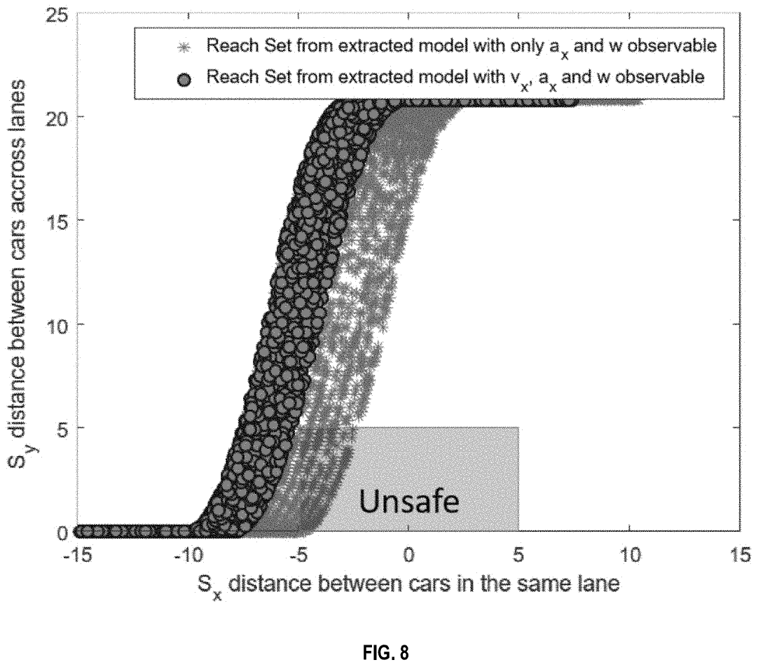

The safety analysis step can then be again performed by the certifier agent 104 of the system 100 with respect to the second reconstructed model 240B from the second subset of operating data 212B. The results can then be compared with the previous reach set from the first subset of operating data 212A when only aₓ and ω were observed. As shown in FIG. 8, the second reconstructed model 240B associated with the second subset of operating data 212B does not intersect with the unsafe set. At this point the certifier agent 104 concludes the iteration and certifies the safety of the CPS model 10.

The system 100 can end the process at this point, or can optionally select a new subset of operating data 212 for analysis. In the aforementioned lane change example of the CPS model 10, the first subset of operating data 212A and the second subset of operating data 212B were already associated with minimal risks, monetary cost and time cost. As such, the process can end at that point with the second subset of operating data 212B being the optimal subset of operating data 212o.

In other embodiments, the system 100 can continue the process with new subsets of operating data 212 (e.g., 212C, . . . , 212n) in an iterative fashion even an affirmative safety evaluation has already been reached in order to identify the optimal subset of operating data 212o. The optimal subset of operating data 212o is associated with optimization of both the first utility function and the second utility function, the first utility function being associated with disclosure cost and risk of the optimal subset of operating data 212o and the second utility function associated with reconstructability and safety of the optimal subset of operating data 212o.

### Process

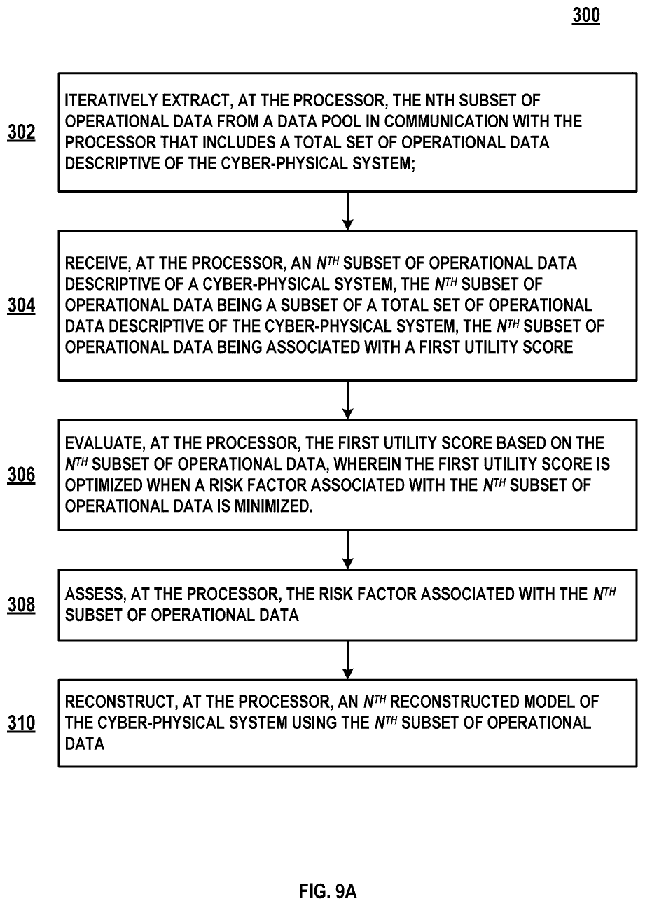

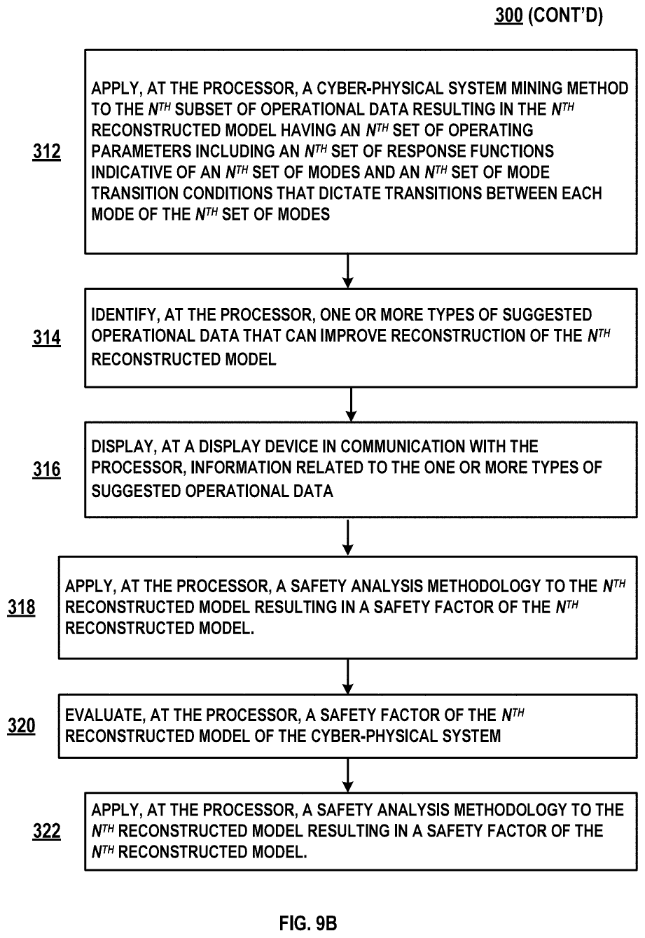

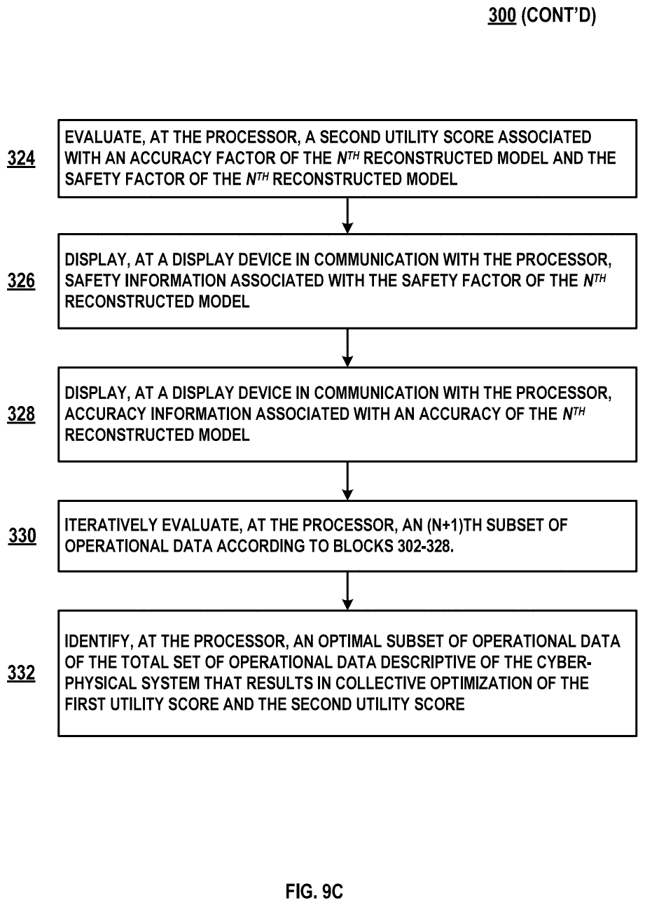

FIGS. 9A-9C provides a method 300 for determining an optimal subset of operating data to be shared between manufacturers and certifier agents for third-party certification of a CPS.

Block 302 of method 300 includes iteratively extracting, at the processor, an nth subset of operating data from a data pool in communication with the processor that includes a total set of operating data descriptive of the cyber-physical system. Block 304 includes receiving, at the processor, an n^{th} subset of operating data descriptive of a cyber-physical system, the n^{th} subset of operating data being a subset of a total set of operating data descriptive of the cyber-physical system, the n^{th} subset of operating data being associated with a first utility score. Block 306 includes evaluating, at the processor, the first utility score based on the n^{th} subset of operating data, wherein the first utility score is optimized when a risk factor associated with the n^{th} subset of operating data is minimized. Block 308 includes assessing, at the processor, the risk factor associated with the n^{th} subset of operating data.

Block 310 includes reconstructing, at the processor, an n^{th} reconstructed model of the cyber-physical system using the n^{th} subset of operating data, and can include various sub-blocks, including block 312, block 314 and block 316. Block 312 includes applying, at the processor, a cyber-physical system mining method to the n^{th} subset of operating data resulting in the n^{th} reconstructed model having an n^{th} set of operating parameters including an n^{th} set of response functions indicative of an n^{th} set of modes and an n^{th} set of mode transition conditions that dictate transitions between each mode of the n^{th} set of modes. Block 314 can be optional, and includes identifying, at the processor, one or more types of suggested operating data that can improve reconstruction of the n^{th} reconstructed model. Block 316 can similarly be optional and includes displaying, at a display device in communication with the processor, information related to the one or more types of suggested operating data.

Block 318 includes applying, at the processor, a safety analysis methodology to the n^{th} reconstructed model resulting in a safety factor of the n^{th} reconstructed model.

Block 320 includes evaluating, at the processor, a safety factor of the n^{th} reconstructed model of the cyber-physical system, and has block 322 as a sub-step that includes applying, at the processor, a safety analysis methodology to the n^{th} reconstructed model resulting in a safety factor of the n^{th} reconstructed model.

Block 324 includes evaluating, at the processor, a second utility score associated with an accuracy factor of the n^{th} reconstructed model and the safety factor of the n^{th} reconstructed model. Block 326 includes displaying, at a display device in communication with the processor, safety information associated with the safety factor of the n^{th} reconstructed model; and block 328 includes displaying, at a display device in communication with the processor, accuracy information associated with an accuracy of the n^{th} reconstructed model.

If the n^{th} subset of operating data is insufficient, then block 330 can be applied. Block 330 includes iteratively evaluating, at the processor, an (n+1)^{th} subset of operating data according to blocks 302-328.

Block 332 includes identifying, at the processor, an optimal subset of operating data of the total set of operating data descriptive of the cyber-physical system that results in collective optimization of the first utility score and the second utility score.

### Computer-Implemented System

FIG. 10 is a schematic block diagram of an example device 400 that may be used with one or more embodiments described herein, e.g., as a component of system 100 and/or shown in FIGS. 1B and 1C.

Device 400 comprises one or more network interfaces 410 (e.g., wired, wireless, PLC, etc.), at least one processor 420, and a memory 440 interconnected by a system bus 450, as well as a power supply 460 (e.g., battery, plug-in, etc.). Further, device 400 can include one or more display devices 425 in communication with processor 420 that displays information to a user.

Network interface(s) 410 include the mechanical, electrical, and signaling circuitry for communicating data over the communication links coupled to a communication network. Network interfaces 410 are configured to transmit and/or receive data using a variety of different communication protocols. As illustrated, the box representing network interfaces 410 is shown for simplicity, and it is appreciated that such interfaces may represent different types of network connections such as wireless and wired (physical) connections. Network interfaces 410 are shown separately from power supply 460, however it is appreciated that the interfaces that support PLC protocols may communicate through power supply 460 and/or may be an integral component coupled to power supply 460.

Memory 440 includes a plurality of storage locations that are addressable by processor 420 and network interfaces 410 for storing software programs and data structures associated with the embodiments described herein. In some embodiments, device 400 may have limited memory or no memory (e.g., no memory for storage other than for programs/processes operating on the device and associated caches).

Processor 420 comprises hardware elements or logic adapted to execute the software programs (e.g., instructions stored within the memory 440 that cause the processor 420 to apply actions dictated by the instructions stored within the memory 440) and manipulate data structures 445. An operating system 442, portions of which are typically resident in memory 440 and executed by the processor, functionally organizes device 400 by, inter alia, invoking operations in support of software processes and/or services executing on the device. These software processes and/or services may include CPS evaluation processes/services 490 which can include a set of instructions within the memory 440 that implement aspects of system 100 and method 300 when executed by the processor 420. Note that while CPS evaluation processes/services 490 is illustrated in centralized memory 440, alternative embodiments provide for the process to be operated within the network interfaces 410, such as a component of a MAC layer, and/or as part of a distributed computing network environment.

It will be apparent to those skilled in the art that other processor and memory types, including various computer-readable media, may be used to store and execute program instructions pertaining to the techniques described herein. Also, while the description illustrates various processes, it is expressly contemplated that various processes may be embodied as modules or engines configured to operate in accordance with the techniques herein (e.g., according to the functionality of a similar process). In this context, the term module and engine may be interchangeable. In general, the term module or engine refers to model or an organization of interrelated software components/functions. Further, while the CPS evaluation processes/services 490 is shown as a standalone process, those skilled in the art will appreciate that this process may be executed as a routine or module within other processes.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

1. A system, comprising:
a processor in communication with a memory, the memory including instructions, which, when executed, cause the processor to:
(1) receive, at the processor, an n^{th} subset of operating data descriptive of a cyber-physical system, the n^{th} subset of operating data being a subset of a total set of operating data descriptive of the cyber-physical system, the n^{th} subset of operating data being associated with a first utility score;
(2) reconstruct, at the processor, an n^{th} reconstructed model of the cyber-physical system using the n^{th} subset of operating data;
(3) evaluate, at the processor, a safety factor of the n^{th} reconstructed model of the cyber-physical system;
(4) evaluate, at the processor, a second utility score associated with an accuracy factor of the n^{th} reconstructed model and the safety factor of the n^{th} reconstructed model; and
(5) identify, at the processor, an optimal subset of operating data of the total set of operating data descriptive of the cyber-physical system that results in collective optimization of the first utility score and the second utility score.

2. The system of claim 1, wherein the optimal subset of operating data is the n^{th} subset of operating data of the total set of operating data when the n^{th} subset of operating data results in collective optimization of the first utility score and the second utility score.

3. The system of claim 1, wherein the memory further includes instructions, which, when executed, cause the processor to:
iteratively apply steps (1)-(4) at the processor using an (n+1)^{th} subset of operating data resulting in an (n+1)^{th} reconstructed model of the cyber-physical system using the (n+1)^{th} subset of operating data; and
iteratively evaluate, at the processor, a collective score of the first utility score and the second utility score with respect to the (n+1)^{th} subset of operating data.

4. The system of claim 3, wherein the optimal subset of operating data is the (n+1)^{th} subset of operating data of the total set of operating data when the (n+1)^{th} subset of operating data results in collective optimization of the first utility score and the second utility score.

5. The system of claim 1, wherein the second utility score is optimized when the accuracy factor and the safety factor associated with the n^{th} subset of operating data are maximized.

6. The system of claim 1, wherein the memory further includes instructions, which, when executed, cause the processor to:
evaluate, at the processor, the first utility score based on the n^{th} subset of operating data, wherein the first utility score is optimized when a risk factor associated with the n^{th} subset of operating data is minimized.

7. The system of claim 6, wherein the memory further includes instructions, which, when executed, cause the processor to:
assess, at the processor, the risk factor associated with the n^{th} subset of operating data, the risk factor including:
a monetary cost score associated with a monetary cost of retrieval and/or disclosure of the n^{th} subset of operating data;
a time cost score associated with a time cost of retrieval and/or disclosure of the n^{th} subset of operating data;
a human risk score associated with a human risk of retrieval and/or disclosure of the n^{th} subset of operating data; and
a confidentiality risk score associated with disclosure of the n^{th} subset of operating data.

8. The system of claim 1, wherein the memory further includes instructions, which, when executed, cause the processor to:
apply, at the processor, a safety analysis methodology to the n^{th} reconstructed model resulting in a safety factor of the n^{th} reconstructed model.

9. The system of claim 8, wherein the safety analysis methodology includes a reach set analysis of the n^{th} reconstructed model.

10. The system of claim 1, wherein the memory further includes instructions, which, when executed, cause the processor to:
display, at a display device in communication with the processor, safety information associated with the safety factor of the n^{th} reconstructed model; and
display, at a display device in communication with the processor, accuracy information associated with an accuracy of the n^{th} reconstructed model.

11. The system of claim 10, wherein the safety information includes an “unsafe” declaration of the n^{th} reconstructed model indicating that the n^{th} reconstructed model results in the safety factor meeting or exceeding a safety threshold value.

12. The system of claim 10, wherein the safety information includes an “unsafe” declaration of the n^{th} reconstructed model indicating that the n^{th} reconstructed model results in the safety factor being below a safety threshold value.

13. The system of claim 10, wherein the accuracy information includes an “inaccurate” declaration of the n^{th} reconstructed model indicating that the n^{th} reconstructed model results in an accuracy factor being below an accuracy threshold value.

14. The system of claim 1, wherein the memory further includes instructions, which, when executed, cause the processor to:
apply, at the processor, a cyber-physical system mining method to the n^{th} subset of operating data resulting in the n^{th} reconstructed model having an n^{th} set of operating parameters including an n^{th} set of response functions indicative of an n^{th} set of modes and an n^{th} set of mode transition conditions that dictate transitions between each mode of the n^{th} set of modes.

15. The system of claim 14, wherein the memory further includes instructions, which, when executed, cause the processor to:
identify, at the processor, one or more types of suggested operating data that can improve reconstruction of the n^{th} reconstructed model; and
display, at a display device in communication with the processor, information related to the one or more types of suggested operating data.

16. The system of claim 1, wherein the memory further includes instructions, which, when executed, cause the processor to:
iteratively extract, at the processor, the n^{th} subset of operating data from a data pool in communication with the processor that includes a total set of operating data descriptive of the cyber-physical system;
iteratively evaluate, at the processor, the n^{th} subset of operating data according to steps (1)-(4);
iteratively extract, at the processor, an (n+1)^{th} subset of operating data from the data pool;
iteratively evaluate, at the processor, the (n+1)^{th} subset of operating data according to steps (1)-(4); and
identify, at the processor, the optimal subset of operating data of the total set of operating data descriptive of the cyber-physical system that results in collective optimization of the first utility score and the second utility score.

17. A method, comprising:
(1) receiving, at a processor in communication with a memory, an n^{th} subset of operating data descriptive of a cyber-physical system, the n^{th} subset of operating data being a subset of a total set of operating data descriptive of the cyber-physical system, the n^{th} subset of operating data being associated with a first utility score;
(2) reconstructing, at the processor, an n^{th} reconstructed model of the cyber-physical system using the n^{th} subset of operating data;
(3) evaluating, at the processor, a safety factor of the n^{th} reconstructed model of the cyber-physical system;
(4) evaluating, at the processor, a second utility score associated with an accuracy factor of the n^{th} reconstructed model and the safety factor of the n^{th} reconstructed model; and
(5) identifying, at the processor, an optimal subset of operating data of the total set of operating data descriptive of the cyber-physical system that results in collective optimization of the first utility score and the second utility score.

18. The method of claim 17, further comprising:
evaluating, at the processor, the first utility score based on the n^{th} subset of operating data, wherein the first utility score is optimized when a risk factor associated with the n^{th} subset of operating data is minimized.

19. The method of claim 17, further comprising:
applying, at the processor, a safety analysis methodology to the n^{th} reconstructed model resulting in a safety factor of the n^{th} reconstructed model.

20. The method of claim 17, further comprising:
applying, at the processor, a cyber-physical system mining method to the n^{th} subset of operating data resulting in the n^{th} reconstructed model having an n^{th} set of operating parameters including an n^{th} set of response functions indicative of an n^{th} set of modes and an n^{th} set of mode transition conditions that dictate transitions between each mode of the n^{th} set of modes.
